(19) United States
(12) Patent Application Publication
(10) Pub. No.: US 2005/0219820 A1
(43) Pub. Date: Oct. 6, 2005

(54) System and method for heat dissipation

(76) Inventors: Christian L. Belady, McKinney, TX (US); Eric Peterson, McKinney, TX (US); Brent A. Boudreaux, Highland Village, TX (US); Shaun L. Harris, McKinney, TX (US); Roy M. Zeighami, McKinney, TX (US)

Correspondence Address: HEWLETT PACKARD COMPANY, P O BOX 272400, 3404 E. HARMONY ROAD, INTELLECTUAL PROPERTY ADMINISTRATION, FORT COLLINS, CO, 80527-2400, US

(21) Appl. No.: 10/816,550

(22) Filed: Apr. 1, 2004

(51) Int. Cl. H05K 7/20

(52) U.S. Cl. 361/700

(57) ABSTRACT

In one embodiment, a thermal dissipation system comprises a plurality of thermal members having surfaces adapted for transferring heat from heat generating elements, a heat sink, and a plurality of heat pipes, each of the heat pipes coupled between a respective one of the plurality of thermal members and the heat sink, wherein the plurality of heat pipes possess a sufficient amount of flexibility to enable each of the plurality of thermal members to be disposed over a range of positions relative to the heat sink.

### RELATED APPLICATION

The present invention is related to U.S. Provisional Patent Application No. 60/455,605, filed Mar. 17, 2003, entitled “Dual-Processor Design,” which is incorporated herein by reference.

### BACKGROUND

An important issue in the design of electronic equipment is the dissipation of thermal energy generated by the electronic equipment. For example, the operating speed of a processor is related to the amount of heat generated by the processor. The amount of heat dissipated by the thermal design of a processor-based system determines the maximum operating speed of the processor.

A number of designs have been implemented to facilitate the dissipation of heat generated by electronic equipment. In applications where spacing requirements are relatively unrestricted and the amount of generated heat is limited, heat sink and fan combinations are typically employed. In applications where spacing requirements are restricted (e.g., laptop computers), heat pipes are frequently employed.

A heat pipe is a passive heat transfer device that exhibits highly efficient thermal conductivity. The efficiency of the thermal conductivity occurs as a result of a two-phase heat transfer mechanism. Specifically, a compound (such as water, methanol, and/or the like) is disposed within a heat pipe. In one physical state or phase of the compound, the compound is liquid. After the introduction of the compound in its liquid form into the heat pipe, the heat pipe is evacuated and sealed. Specifically, the pressure in the heat pipe is reduced so that application of a relatively small amount of heat causes the compound to change phase. In operation, the heat generated by the electronic equipment is conducted through the heat pipe and into the compound at the “evaporator.” The vaporization of the compound in the heat pipe generates a pressure gradient thereby forcing the vapor to flow towards a cooling structure (the “condenser”). The cooling structure causes the vapor to condense and transfers the latent heat of evaporation from the heat dissipation system. The condensate returns to the evaporator by gravity and/or by capillary action.

### SUMMARY

In one embodiment, a thermal dissipation system comprises a plurality of thermal members having surfaces adapted for transferring heat from heat generating elements, a heat sink, and a plurality of heat pipes, each of the heat pipes coupled between a respective one of the plurality of thermal members and the heat sink, wherein the plurality of heat pipes possess a sufficient amount of flexibility to enable each of the plurality of thermal members to be disposed over a range of positions relative to the heat sink.

In another embodiment, a method of assembling a heat dissipating system comprises providing a heat sink, thermally coupling a plurality of heat pipes to the heat sink, thermally and mechanically coupling a respective thermal member to each of the plurality of heat pipes, wherein the plurality of heat pipes possess sufficient flexibility to enable the thermal members to be positioned through a range of positions relative to the heat sink, and thermally coupling heat generating elements to the thermal members.

In another embodiment, a system for dissipating heat comprises means for dissipating heat, a plurality of means for transferring heat, by phase-changing an evaporate, that possess positioning tolerance, and a plurality of means for receiving heat generating elements over a range of positions relative to the means for dissipating, wherein each of the plurality of means for receiving is coupled to a respective one of the plurality of means for transferring.

In another embodiment, a processor package assembly comprises a first packing layer comprising a plurality of heat generating logic circuits, a second packaging layer comprising a power supply unit for supplying power to the plurality of heat generating logic circuits, a plurality of thermal members thermally coupled to the plurality of heat generating logic circuits, a plurality of heat pipes thermally coupled to the thermal members extending from the plurality of thermally members in a lateral direction relative to the first and second packaging layers, and a heat sink thermally coupled to the plurality of heat pipes and to the power supply unit, wherein the plurality of heat pipes possess positioning flexibility through a range of positions relative to the heat sink.

### BRIEF DESCRIPTION OF THE DRAWINGS

FIG. 1 depicts a thermal dissipation system according to one representative embodiment.

FIGS. 2A-2B depicts other thermal dissipation systems according to representative embodiments.

FIG. 3 depicts a flowchart for assembly of a thermal dissipation system according to one representative embodiment.

FIG. 4 depicts stacked packaging structure from which one representative embodiment may dissipate heat using a plurality of heat pipes.

FIG. 5 depicts a typical daughtercard layout for operation with a heat pipe system.

FIG. 6 depicts a stacked packaging structure according to one representative embodiment.

### DETAILED DESCRIPTION

FIG. 5 depicts “daughtercard” layout 500 that can be cooled using heat pipe designs. Layout 500 includes power unit 501, processor 502, and cache memory application specific integrated circuit (ASIC) 503. Layout 500 is typical of single-processor architectures. As shown in FIG. 5, layout 500 is two dimensional. Specifically, power unit 501, processor 502, and cache memory ASIC 503 reside in the same plane. The term “plane” as used herein refers to the same layer of a stacked multi-layer processor package or the like Accordingly, a single heat transfer element (e.g., a suitably machined sheet of metal) can be readily coupled to these heat generating devices. A heat pipe can then be mechanically and thermally coupled to the heat transfer element to dissipate the heat generated by power unit 501, processor 502, and cache memory 503.

In some representative embodiments, a thermal dissipation system employs a plurality of heat pipes arranged according to a network configuration to enable heat to be dissipated from devices located in a plurality of planes. Specifically, a plurality of independent thermal members are disposed at various positions. The thermal members are thermally and mechanically coupled to heat pipes at their respective evaporators. At the other end of the heat pipes (i.e., at the condensers), the heat pipes are thermally and mechanically coupled to a common heat sink. Each heat pipe extends a relatively long distance from the thermal members. Also, each heat pipe possesses a “bend” proximate to the mechanical coupling to the heat sink. Because of the configuration of the heat pipes, each thermal member exhibits a relatively significant amount of positioning “z-tolerance.” Due to the tolerance, thermal dissipation system 100 enables a greater range of electronic system designs that are not constrained to disposing each heat generating element within the same plane.

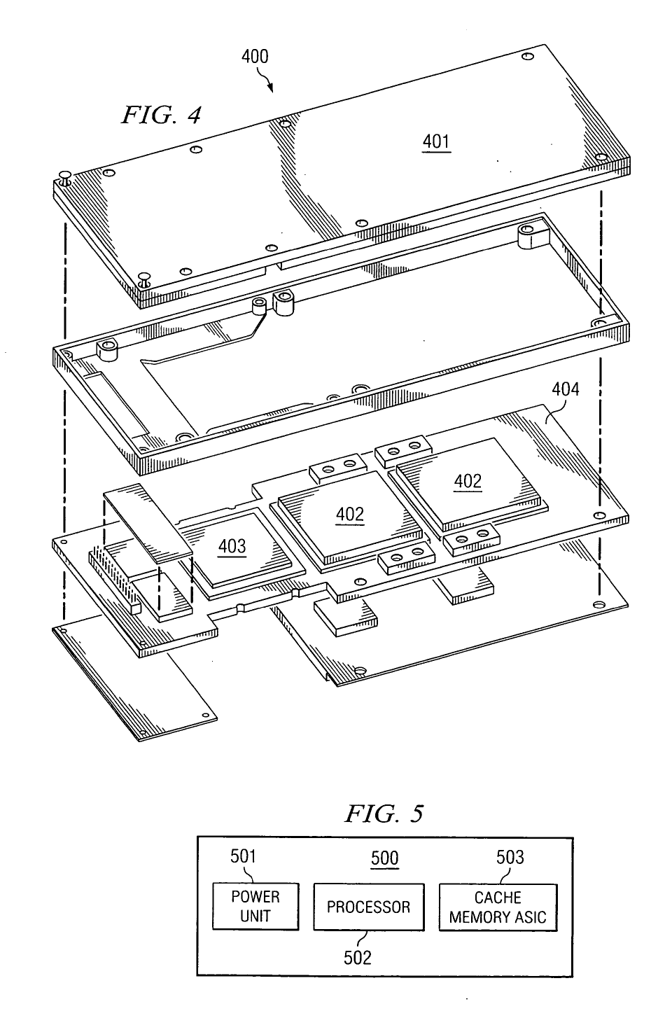

In one representative embodiment, a thermal dissipation system is designed to dissipate heat from a processor package that does not dispose heat generating elements in a two-dimensional manner. For example, one representative embodiment dissipates heat from the dual processor package shown in U.S. Provisional Patent Application No. 60/455,605, entitled “Dual-Processor Design” using a plurality of heat pipes. FIG. 4 depicts stacked packaging structure 400 adapted according to a dual processor design that may receive heat dissipation by one representative embodiment. As shown in FIG. 4, daughtercard 404 includes a plurality of means for processing data (such as processors 402) and cache memory ASIC 403. Due to the spacing constraints of packing structure 400, there is insufficient space within the same plane that has processors 402 and cache memory 403 to include a means for supplying power. Accordingly, stacked packaging structure 400 disposes the means for supplying power (such as power supply unit 401) in a separate plane above these elements. Thus, stacked packaging structure 400 contains a plurality elements that would benefit from heat dissipating that are not contained within the same plane and, thus, are not amenable to heat dissipation using typical heat pipe designs.

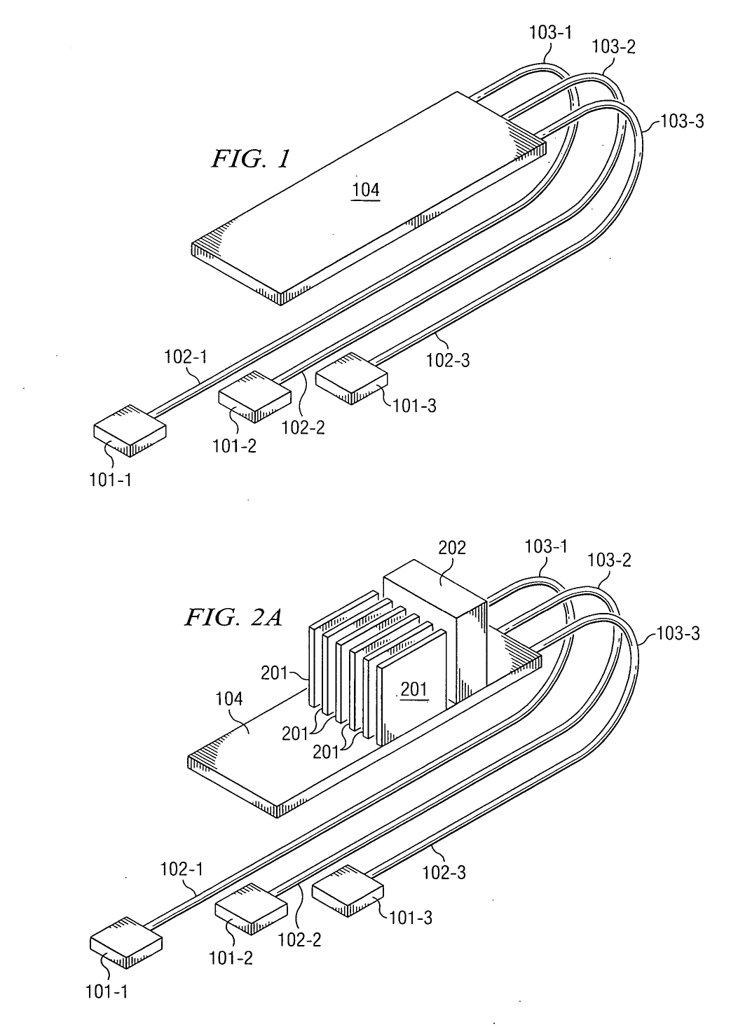

FIG. 1 depicts thermal dissipation system 100 according to one representative embodiment that enables dissipation of heat from devices located in multiple planes. As shown in FIG. 1, thermal dissipation system 100 may include multiple means for receiving heat generating elements such as thermal members 101-1, 101-2, and 101-3. Specifically, thermal members 01 possess a relatively flat surface area to provide sufficiently low contact resistance with a heat generating element. Various types of electronic equipment and related elements may be coupled to each thermal member 101. For example, processors 402 and cache memory ASIC 403 of FIG. 4 could be coupled to respective thermal members 101. Of course, any combination of heat generating elements can be coupled to thermal members 101 as desired for a specific application. Also, although three thermal members 101 are shown in FIG. 1, any number of thermal members 101 may be implemented according to representative embodiments.

Thermal dissipation system 100 further includes a plurality of means for transferring heat by phase-changing an evaporate such as heat pipes 102-1, 102-2, and 102-3. Heat pipes 102-1, 102-2, and 102-3 are thermally and mechanically coupled to respective thermal members 101-1, 101-2, and 101-3. Heat pipes 102 could be implemented using typical materials such as copper. Alternatively, heat pipes 102 could be implemented using other materials that possess relatively high conductivity (e.g., carbon fiber structures). Each heat pipe 102 possesses an evacuated interior having a suitable phase-change compound for evaporation proximate to thermal members 101. Also, each heat pipe 102 includes a “wick” or other suitable structure to enable the return of the condensate. By appropriately selecting its pore radius and permeability, the wick serves as a pump applying capillary pressure to return the condensate to the evaporator.

Heat pipes 102 are coupled in a network configuration to a means for dissipating heat such as heat sink 104. Heat sink 104 receives the heat of evaporation from heat pipes 102 to transfer heat from heat dissipation system 100 into the surrounding environment. Also, when system 100 is employed to dissipate heat from stacked packaging structure 400, power supply unit 401 may thermally contact heat sink 104 to dissipate heat from power supply unit 401.

Heat pipes 102-1, 102-2, and 102-3 extend differing lengths from thermal members 101. The lengths may be selected according to the defined positions of the components of the system that will benefit from the heat dissipation. Also, the lengths of heat pipes 102 are selected in relation to the curvature of bends 103-1, 103-2, 103-3. Specifically, the appropriate selection of the lengths of heat pipes 102 and the curvatures of bends 103 enables the desired degree of “z-tolerance.” Specifically, each thermal member 101 may be disposed over a range of positions in the z-axis (an axis extending perpendicular to the stacked planes of packaging structure 400) due to the tolerance. The tolerance may be used to accommodate heat generating devices having varying profiles. Additionally or alternatively, the tolerance may be used to enable a greater range of non-planar designs for electronic equipment as desired. The tolerance may cause the assembly of the system to occur in a more efficient manner.

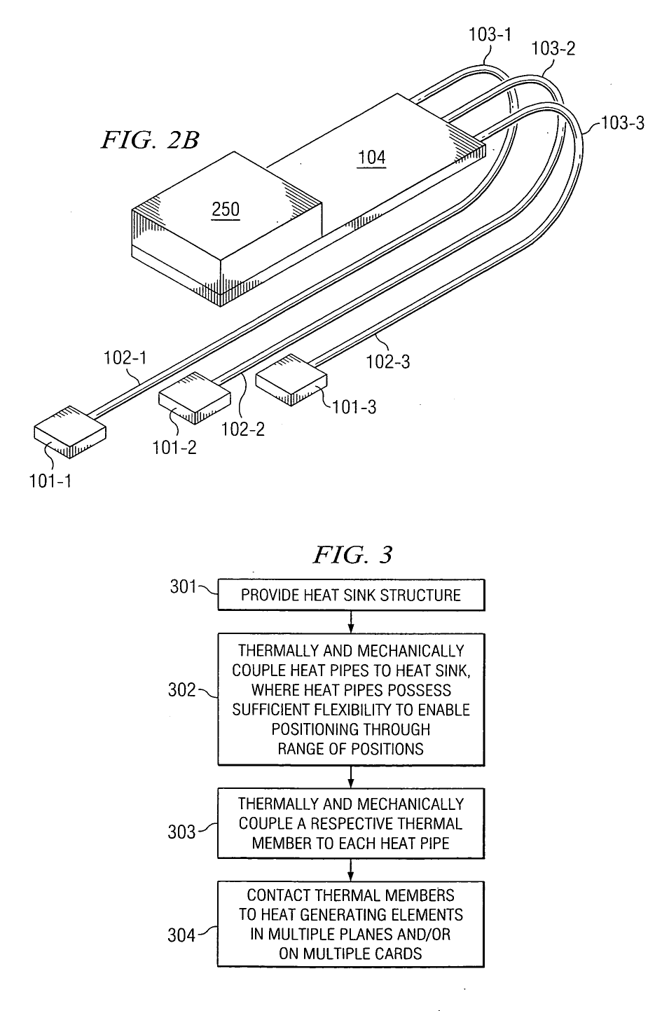

The design of thermal dissipation system 100 shown in FIG. 1 is by way of example. Variations of the design may be made in accordance with representative embodiments. For example, as shown in FIG. 2A, thermal dissipation system 200 includes a heat sink 104 having a plurality of finned members 201. The plurality of finned members 201 may be used to increase the surface area associated with heat sink 104. A fluid displacement means (such as fan 202) may be disposed proximate to the finned members. Fan 202 increases the air flow through finned members 201 to facilitate the rate of the heat dissipation. Although a fan and finned members are shown, other cooling mechanisms may be alternatively employed. For example, sub-cooling structure 250 may employ refrigeration functionality to dissipate heat from heat sink 104 as shown in FIG. 2B. Also, although heat dissipation has been described as occurring for devices associated with a single card, representative embodiments are not so limited. For example, each thermal member 101 could contact a heat generating element located on a respective card if desired for a particular application.

FIG. 3 depicts a flowchart for assembling a thermal dissipation system according to one representative embodiment. In step 301, a suitable heat sink structure is provided. In step 302, a plurality of heat pipes are thermally and mechanically coupled to the heat sink structure. In step 303, a respective thermal member is thermally and mechanically coupled to each of the plurality of heat pipes. The heat pipes possess sufficient flexibility to enable the thermal members to be positioned through a range of positions relative to said heat sink. Accordingly, in step 304, the thermal members may be contacted with heat generating elements on different planes and, potentially, on different cards.

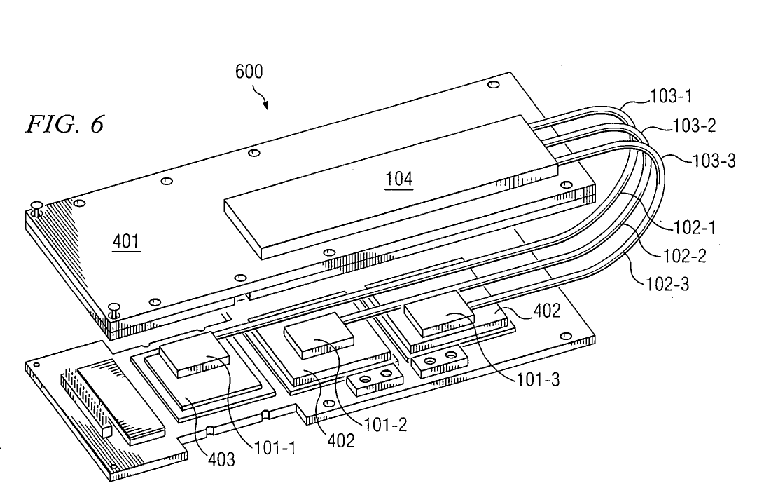

FIG. 6 is an exploded view of stacked packaging structure 600, like structure 400, but with a thermal dissipation system provided thereon. Specifically, FIG. 6 depicts thermal members 101-1, 101-2, and 101-3 thermally contacting a plurality of heat generating logic circuits such as ASIC 403 and processors 402. All or a subset of the heat generating logic circuits may possess differing vertical profiles due to the positioning tolerance associated with thermal members 101-1, 101-2, and 101-3. Heat pipes 102-1 through 102-3 extend away from their respective heating generating elements. Bends 103-1 through 103-3 enable heat sink 104 to contact power supply unit 401 which is located in a separate plane. The thermal energy generated by the logic circuits (processors 402 and ASIC 403) is transported from inside stacked packaging structure 600 to its exterior. Due to the transport of the thermal energy, the thermal energy may be dissipated by heat sink 104. Furthermore, the thermal energy generated by power supply unit 401 is also dissipated by heat sink 104.

Some representative embodiments may enable a number of advantages. For example, using the positioning tolerance, heat generating elements of a suitable electronic or other system are coupled to said thermal members according to a non-planar architecture. The non-planar architectures may enable a greater number of electronic or other heat generating elements to be packaged in a relatively small amount of space.

1. A thermal dissipation system, comprising:
a plurality of thermal members having surfaces adapted for transferring heat from heat generating elements;
a heat sink; and
a plurality of heat pipes, each of the heat pipes coupled between a respective one of said plurality of thermal members and said heat sink, wherein said plurality of heat pipes possess a sufficient amount of flexibility to enable each of said plurality of thermal members to be disposed over a range of positions relative to said heat sink.

2. The thermal dissipation system of claim 1 wherein each of said plurality of heat pipes comprises a respective bend to provide said sufficient amount of flexibility.

3. The thermal dissipation system of claim 1 wherein each of said plurality of thermal members are disposed at different lengths defined by terminal ends of said plurality of heat pipes.

4. The thermal dissipation system of claim 1 wherein said heat sink is a finned heat sink.

5. The thermal dissipation system of claim 1 further comprising:
a fan disposed proximate to said heat sink.

6. The thermal dissipation system of claim 1 further comprising:
a refrigeration-based unit adapted to sub-cool said heat sink.

7. A method of assembling a heat dissipating system, comprising:
providing a heat sink;
thermally coupling a plurality of heat pipes to said heat sink;
thermally and mechanically coupling a respective thermal member to each of said plurality of heat pipes, wherein said plurality of heat pipes possess sufficient flexibility to enable said thermal members to be positioned through a range of positions relative to said heat sink; and
thermally coupling heat generating elements to said thermal members.

8. The method of claim 7 wherein said heat generating elements include a processor.

9. The method of claim 7 further comprising:
thermally coupling a power supply to said heat sink.

10. The method of claim 7 wherein each of said plurality of heat pipes possess a bend to provide said sufficient flexibility.

11. The method of claim 7 wherein said heat sink possesses a plurality of finned elements.

12. The method of claim 7 further comprising:
disposing a fan unit proximate to said heat sink.

13. The method of claim 7 further comprising:
providing a refrigeration-based unit to sub-cool said heat sink.

14. A system for dissipating heat, comprising:
means for dissipating heat;
a plurality of means for transferring heat, by phase-changing an evaporate, that possess positioning tolerance; and
a plurality of means for receiving heat generating elements over a range of positions relative to said means for dissipating, wherein each of said plurality of means for receiving is coupled to a respective one of said plurality of means for transferring.

15. The system of claim 14 further comprising:
means for processing data coupled to one of said means for receiving.

16. The system of claim 14 further comprising:
means for supplying power coupled to said means for dissipating.

17. The system of claim 14 wherein said means for dissipating possesses a plurality of fin elements.

18. The system of claim 14 further comprising:
a fluid displacement means coupled to said means for dissipating.

19. The system of claim 14 wherein each of said plurality of means for receiving is disposed at differing lengths as defined by terminal ends of said plurality of means for transferring.

20. The system of claim 14 wherein said plurality of means for receiving thermally contact heat generating elements located on respective electronic cards.

21. A processor package assembly, comprising:
a first packing layer comprising a plurality of heat generating logic circuits;
a second packaging layer comprising a power supply unit for supplying power to said plurality of heat generating logic circuits;
a plurality of thermal members thermally coupled to said plurality of heat generating logic circuits;
a plurality of heat pipes thermally coupled to said thermal members extending from said plurality of thermally members in a lateral direction relative to said first and second packaging layers; and
a heat sink thermally coupled to said plurality of heat pipes and to said power supply unit, wherein said plurality of heat pipes possess positioning flexibility through a range of positions relative to said heat sink.

22. The processor package assembly of claim 21 wherein said plurality of heat generating logic circuits comprise a plurality of processors.

23. The processor package assembly of claim 21 wherein said plurality of heat generating logic circuits comprise a cache memory application specific integrated circuit (ASIC).

24. The processor package assembly of claim 21 wherein at least a subset of said plurality of heat generating logic circuits possess differing vertical profiles relative to said first packaging layer.
